(19) United States
(12) Patent Application Publication
(10) Pub. No.: US 2016/0056324 A1
(43) Pub. Date: Feb. 25, 2016

(54) LIGHT ENHANCEMENT OF LIGHT EMITTING DIODES

(71) Applicant: Melvin Feinstein, Remsenburg, NY (US)

(72) Inventor: Melvin Feinstein, Remsenburg, NY (US)

(21) Appl. No.: 14/462,673

(22) Filed: Aug. 19, 2014

(51) Int. Cl. H01L 33/00; H01L 33/42; H01L 33/32; H01L 33/58; H01L 33/06; H01L 33/22

(52) U.S. Cl. CPC H01L 33/0025; H01L 33/06; H01L 33/22; H01L 33/32; H01L 33/58; H01L 33/42; H01L 2933/0058

(57) ABSTRACT

A multi-layered semiconductor die having an ITO layer being the topmost layer with a predetermined and generally uniform thickness. A ZnO seed layer with a predetermined and generally uniform thickness is sputtered the ITO layer, forming a generally roof shingle pattern with the ITO layer. The seed layer has a periphery having a generally beveled edge, which is operable to enhance light emitted by a light source. A ZnO nanostructure layer is deposited on top of the seed layer including at least two or more nanocone arrays. The nanocone arrays are configured to have bases and tips and the bases are configured to be in close proximity so as to be almost touching but not connected. Gaps are formed between each tip of each nanocone array. The nanostructure being operable to enhance light dispersion of the light source.

### CROSS-REFERENCE TO RELATED APPLICATIONS

Not Applicable.

### RELATED CO-PENDING U.S. PATENT APPLICATIONS

Not Applicable.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection. The copyright owner has no objection to the facsimile reproduction by anyone of the patent document or patent disclosure as it appears in the Patent and Trademark Office, patent file or records, but otherwise reserves all copyright rights whatsoever.

### FIELD OF THE INVENTION

One or more embodiments of the invention generally relate to light sources. More particularly, the invention relates to coating light sources.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

Light sources may increase in value from producing greater illumination for a given wattage. Currently available light sources, including, without limitation, LED lights, may lack effective coatings which may increase illumination of such light sources. A solution which provided improved illumination from coating light sources would be desirable.

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is an illustration of an exemplary coated GaN-based semiconductor die, in accordance with an embodiment of the present invention; and

FIG. 2 is an illustration of an exemplary method for coating light sources, in accordance with an embodiment of the present invention.

Unless otherwise indicated illustrations in the figures are not necessarily drawn to scale.

### DETAILED DESCRIPTION OF SOME EMBODIMENTS

The present invention is best understood by reference to the detailed figures and description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will now be described in detail with reference to embodiments thereof as illustrated in the accompanying drawings.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present application or of any further application derived therefrom.

References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic. Further, repeated use of the phrase “in one embodiment,” or “in an exemplary embodiment,” do not necessarily refer to the same embodiment, although they may.

Headings provided herein are for convenience and are not to be taken as limiting the disclosure in any way.

The enumerated listing of items does not imply that any or all of the items are mutually exclusive, unless expressly specified otherwise.

The terms “a”, “an” and “the” mean “one or more”, unless expressly specified otherwise.

Devices or system modules that are in at least general communication with each other need not be in continuous communication with each other, unless expressly specified otherwise. In addition, devices or system modules that are in at least general communication with each other may communicate directly or indirectly through one or more intermediaries.

A description of an embodiment with several components in communication with each other does not imply that all such components are required. On the contrary a variety of optional components are described to illustrate the wide variety of possible embodiments of the present invention.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

It is to be understood that any exact measurements/dimensions or particular construction materials indicated herein are solely provided as examples of suitable configurations and are not intended to be limiting in any way. Depending on the needs of the particular application, those skilled in the art will readily recognize, in light of the following teachings, a multiplicity of suitable alternative implementation details.

Some embodiments of the present invention may provide means and/or methods for enhancing light extraction from various light sources, including, without limitation, light-emitting diodes (LEDs). In some embodiments, light may be extracted by coating a surface of a light source.

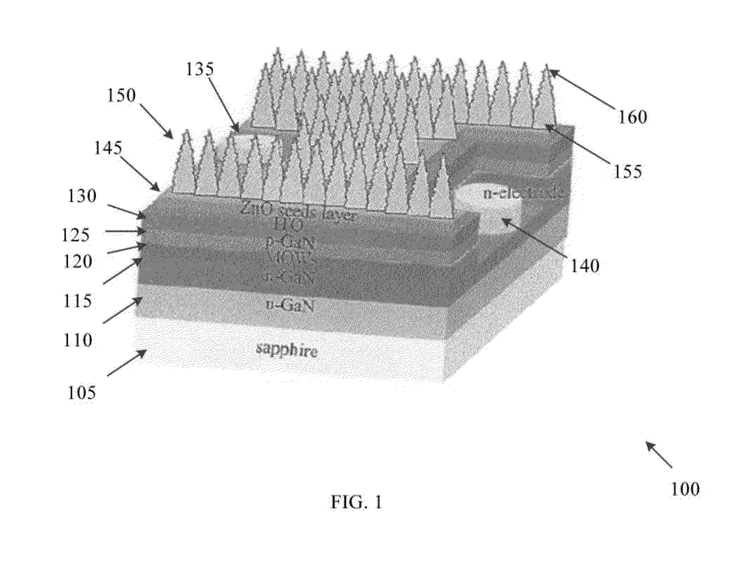

FIG. 1 is an illustration of an exemplary coated GaN-based semiconductor die, in accordance with an embodiment of the present invention. In the present embodiment, a die 100 may have multiple layers, including, without limitation, sapphire 105, undoped GaN 110, n-GaN 115, InGaN/GaN multiple-quantum-Well (MQW) 120, p-GaN 125, indium tin oxide (ITO) 130, and p 135 and n 140 Ni/Au electrodes. In a non-limiting example, sapphire layer 105 may have thickness of approx. 400 μm, undoped GaN layer 110 may have thickness of 2 approx. μm, n-GaN layer 115 may have thickness of 2 approx. μm, MQW layer 120 may be composed of five periods of InGaN/GaN MQW, p-GaN layer 125 may have thickness of approx. 250 nm, and ITO layer 130 may have thickness of approx. 200 nm. In the present embodiment, die 100 may be coated with a ZnO seed layer 145 and one or more ZnO nanocone arrays 150. In a non-limiting example, the layers shall be arranged in a substantially roof shingle pattern with generally beveled edges for maximum enhancement of the light produced by the diode. In a non-limiting example, a nanocone array 150 may have a length of approx. 1 μm and may have a bottom diameter of approx. 200 nm. In some embodiments, nanocone arrays 150 may have rough surfaces which may be covered with bulges. In one embodiment, bases 155 of nanocone arrays 150 may be close to each other so as to almost be connected, while tips 160 of nanocone arrays 150 may have gaps between each other. In a non-limiting example, nanocone arrays 150 may have vertex angles (angle between sides of array 150, from tip 160) between 13° and 17°. In a non-limiting example, nanorods may be used in place of nanocones.

In some instances, geometry and/or morphology of ZnO nanostructures may be sensitive to reaction parameters, such as, without limitation, growth temperature, pH of precursor, growth time, seed crystals, impurities, etc. In some embodiments, nanocone arrays 150 may be designed to grow with a roughened surface, and by doing so, increase photo scattering and more light increases light dispersion. In some embodiments, the nanocone arrays are formed in an isosceles triangle with an apex angle of approximately 17 degrees to produce maximum light dispersion. In some of these embodiments, one may use lower temperatures in growing process to produce nanocone arrays 150 having rough surfaces, due to vulnerability of Ni/Au electrodes to temperature. In many embodiments, ZnO nanocone arrays 150 and/or other types of coating may be only be deposited on ITO electrode 130 of a p-GaN layer 125, and rest of area of LED and/or other light source may be free from damage. In some of these embodiments, one may employ a photoresist lift-off process to effectively deposit coating on desired surfaces.

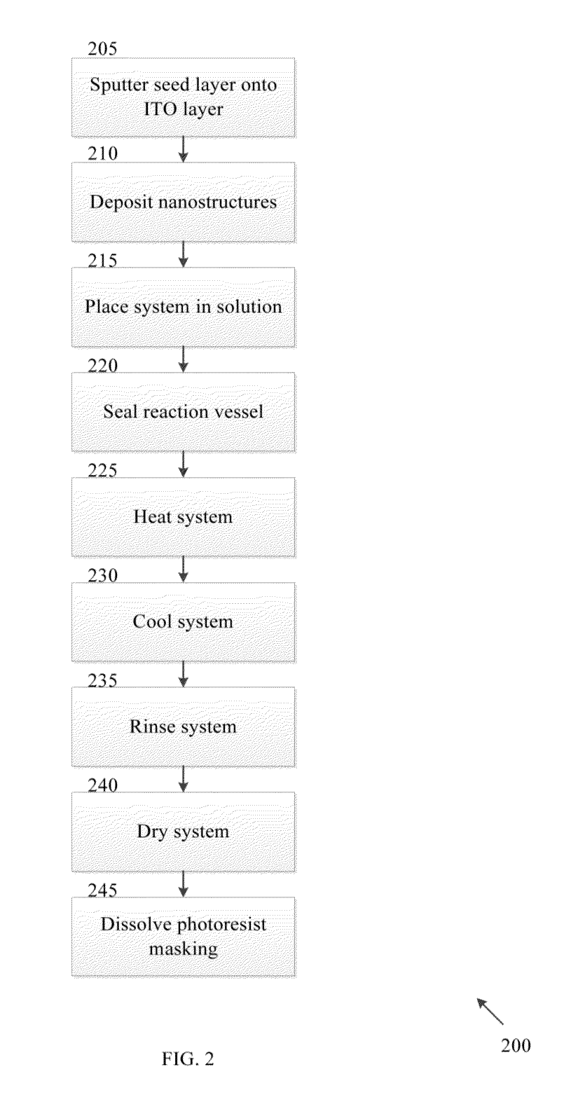

FIG. 2 is an illustration of an exemplary method for coating light sources, in accordance with an embodiment of the present invention. In the present embodiment, one may uniformly sputter a seed layer 145 onto an ITO layer 130 in a step 205. In a non-limiting example, seed layer 145 may have a thickness of 100 nm and may be composed of transparent compact crystalline ZnO. In some embodiments, one may use a magnetron sputtering apparatus to sputter seed layer 145. In the present embodiment, one may deposit nanostructures 150 in a step 210. In a non-limiting example, nanostructures 150 may be composed of ZnO. In the present embodiment, one may place system 100 face-down in a solution in a step 215. In a non-limiting example, a suitable solution may be composed of 10 mL 50 mM zinc nitrate ((ZnNO3)2) and 10 mL 50 mM hexamethylenetetramine (HMT) (C6H12N4). In some embodiments, solution may be mixed and transferred to a 25 mL Teflon autoclave which may be placed into a sealed reaction vessel. In the present embodiment, one may seal a reaction vessel containing system 100 in a step 220. In some instances, sealing reaction vessel may help in avoiding evaporation of reaction solution. In some embodiments, reaction system may be kept at a stable pressure. In the present embodiment, one may heat system 100 in an oven in a step 225. In a non-limiting example, system 100 may be heated from ambient temperature to 95° C. for 0.5 h and may be maintained at 95° C. for approx. 2.5 h. In some embodiments, oven may be a standard laboratory grade oven. In the present embodiment, one may cool system 100 in a step 230. In a non-limiting example, system 100 may be cooled to ambient temperature. In some embodiments, cooling may be performed naturally. In the present embodiment, one may rinse system 100 in a step 235. In a non-limiting example, system 100 may be rinsed with de-ionized water. In some embodiments, rinsing may be suitable for removing any residual salt. In the present embodiment, one may dry system 100 in a step 240. In a non-limiting example, system 100 may be dried in high-purity nitrogen at room temperature. In the present embodiment, one may dissolve photoresist masking in a step 245. In some embodiments, one may use photoresist remover to dissolve photoresist masking. In a non-limiting example, one may apply photoresist remover at 55° C. for approx. 0.5 h.

In some embodiments, p 135 and/or n 140 electrodes and/or lateral faces of LED 100 may be exposed to open space. In one embodiment, ZnO nanocone arrays 150 may be grown only on surface of ITO 130 transparent electrodes.

In other embodiments, ZnO nanocone arrays 150 may be prepared by suspending a sample upside-down in a glass beaker filled with an aqueous solution of 50 mM Zn(NO3)2 and 50 mM HMT at 90° C. for 3 h. In some of these embodiments, LED 100 may be rinsed with de-ionized water and dried in high purity nitrogen at room temperature.

Some embodiments may be suitable for improving lumen output of LED lights by 100%. Many LED lighting products may benefit from such improvements, including, without limitation, spot lights, panel lights, etc.

Many embodiments may function best in an electrically wired tube. In some embodiments, a rigid frame is more desirable than one that is not.

Those skilled in the art will readily recognize, in light of and in accordance with the teachings of the present invention, that any of the foregoing steps may be suitably replaced, reordered, removed and additional steps may be inserted depending upon the needs of the particular application. Moreover, the prescribed method steps of the foregoing embodiments may be implemented using any physical and/or hardware system that those skilled in the art will readily know is suitable in light of the foregoing teachings. For any method steps described in the present application that can be carried out on a computing machine, a typical computer system can, when appropriately configured or designed, serve as a computer system in which those aspects of the invention may be embodied. Thus, the present invention is not limited to any particular tangible means of implementation.

All the features disclosed in this specification, including any accompanying abstract and drawings, may be replaced by alternative features serving the same, equivalent or similar purpose, unless expressly stated otherwise. Thus, unless expressly stated otherwise, each feature disclosed is one example only of a generic series of equivalent or similar features.

It is noted that according to USA law 35 USC §112 (1), all claims must be supported by sufficient disclosure in the present patent specification, and any material known to those skilled in the art need not be explicitly disclosed. However, 35 USC §112 (6) requires that structures corresponding to functional limitations interpreted under 35 USC §112 (6) must be explicitly disclosed in the patent specification. Moreover, the USPTO's Examination policy of initially treating and searching prior art under the broadest interpretation of a “mean for” claim limitation implies that the broadest initial search on 112(6) functional limitation would have to be conducted to support a legally valid Examination on that USPTO policy for broadest interpretation of “mean for” claims. Accordingly, the USPTO will have discovered a multiplicity of prior art documents including disclosure of specific structures and elements which are suitable to act as corresponding structures to satisfy all functional limitations in the below claims that are interpreted under 35 USC §112 (6) when such corresponding structures are not explicitly disclosed in the foregoing patent specification. Therefore, for any invention element(s)/structure(s) corresponding to functional claim limitation(s), in the below claims interpreted under 35 USC §112 (6), which is/are not explicitly disclosed in the foregoing patent specification, yet do exist in the patent and/or non-patent documents found during the course of USPTO searching, Applicant(s) incorporate all such functionally corresponding structures and related enabling material herein by reference for the purpose of providing explicit structures that implement the functional means claimed. Applicant(s) request(s) that fact finders during any claims construction proceedings and/or examination of patent allowability properly identify and incorporate only the portions of each of these documents discovered during the broadest interpretation search of 35 USC §112 (6) limitation, which exist in at least one of the patent and/or non-patent documents found during the course of normal USPTO searching and or supplied to the USPTO during prosecution. Applicant(s) also incorporate by reference the bibliographic citation information to identify all such documents comprising functionally corresponding structures and related enabling material as listed in any PTO Form-892 or likewise any information disclosure statements (IDS) entered into the present patent application by the USPTO or Applicant(s) or any 3^{rd} parties. Applicant(s) also reserve its right to later amend the present application to explicitly include citations to such documents and/or explicitly include the functionally corresponding structures which were incorporate by reference above.

Thus, for any invention element(s)/structure(s) corresponding to functional claim limitation(s), in the below claims, that are interpreted under 35 USC §112 (6), which is/are not explicitly disclosed in the foregoing patent specification, Applicant(s) have explicitly prescribed which documents and material to include the otherwise missing disclosure, and have prescribed exactly which portions of such patent and/or non-patent documents should be incorporated by such reference for the purpose of satisfying the disclosure requirements of 35 USC §112 (6). Applicant(s) note that all the identified documents above which are incorporated by reference to satisfy 35 USC §112 (6) necessarily have a filing and/or publication date prior to that of the instant application, and thus are valid prior documents to incorporated by reference in the instant application.

Having fully described at least one embodiment of the present invention, other equivalent or alternative methods of implementing coating according to the present invention will be apparent to those skilled in the art. Various aspects of the invention have been described above by way of illustration, and the specific embodiments disclosed are not intended to limit the invention to the particular forms disclosed. The particular implementation of the coating may vary depending upon the particular context or application. By way of example, and not limitation, the described in the foregoing were principally directed to light source implementations; however, similar techniques may instead be applied to any semiconductor dies, which implementations of the present invention are contemplated as within the scope of the present invention. The invention is thus to cover all modifications, equivalents, and alternatives falling within the spirit and scope of the following claims. It is to be further understood that not all of the disclosed embodiments in the foregoing specification will necessarily satisfy or achieve each of the objects, advantages, or improvements described in the foregoing specification.

Claim elements and steps herein may have been numbered and/or lettered solely as an aid in readability and understanding. Any such numbering and lettering in itself is not intended to and should not be taken to indicate the ordering of elements and/or steps in the claims.

The corresponding structures, materials, acts, and equivalents of all means or step plus function elements in the claims below are intended to include any structure, material, or act for performing the function in combination with other claimed elements as specifically claimed.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. A device comprising:
a multiple layered semiconductor die, said semiconductor die being comprise of;
an ITO layer, said ITO layer being configured to have a predetermined and generally uniform thickness;
a ZnO seed layer comprising a predetermined and generally uniform thickness, said seed layer being configured to be substantially bonded with said ITO layer to form a generally roof shingle pattern with said ITO layer, said seed layer being configured with a periphery having a generally beveled edge, which is operable to enhance light emitted by a light source;
a nano structure layer, said nano structure layer being configured to substantially fuse with said seed layer, said nano structure layer comprising at least one nanocone array, said nanocone array being configured with a base and a tip, said nano structure being operable to enhance light dispersion of said light source.

2. The device of claim 1, in which said multi-layered semiconductor die further comprise of;
a p-GaN layer, said a p-GaN layer being configured to bond with said ITO layer and an MQW layer;
an undoped GaN layer, said undoped GaN layer being configured to bond with an n-GaN layer and a sapphire base layer;
p and n electrodes, said p and n electrodes being configured to fuse with said n-GaN layer.

3. The device of claim 2, in which said at least one nanocone array further comprise of at least two or more nanocone arrays, said at least two or more nanocone arrays being configured with bases and tips, said bases of said at least two or more nanocone arrays being configured to be in close proximity so as to be almost touching but not connected, said tips of said nanocone arrays being configured to form a gap between each tip of each of said nanocone array.

4. The device of claim 1, in which said nanocone arrays comprise of generally pyramidal or cone shaped ZnO nanocone array.

5. The device of claim 4, in which said nanocone arrays further comprise of vertex angle of approximately 13 degrees to 17 degrees.

6. The device of claim 4, in which said nanocone arrays further comprise of generally isosceles triangle with apex angle of approximately 17 degrees.

7. The device of claim 4, in which said nanocone arrays further comprise of substantially roughened surfaces.

8. The device of claim 1, in which said nanocone arrays further comprise of ZnO nanocone arrays.

9. A method of processing a multi-layered semiconductor die, said method comprising the steps of:
uniformly and substantially sputtering a seed layer onto an ITO layer of said semiconductor die while maintaining a predetermined thickness of said seed layer;
depositing at least one nanostructure upon or at least partially into an upper surface portion of said seed layer;
placing said semiconductor die with said at least one nano structure, face-downward towards a solution;
sealing a reaction vessel substantially enclosing said semiconductor die and said at least one nanostructure, and placing in said solution;
heating said sealed reaction vessel;
cooling said reaction vessel substantially enclosing said semiconductor die and said at least one nanostructure;
rinsing said cooled semiconductor die and said at least one nanostructure;
drying said rinsed semiconductor die and said at least one nanostructure; and
substantially dissolving photoresist masking off of said dried semiconductor die and said at least one nanostructure.

10. The method of claim 9, further comprising the step of arranging said seed layer in a substantially roof shingle pattern with said ITO layer.

11. The method of claim 9, further comprising the step of forming generally beveled edges along periphery of said seed layer.

12. The method of claim 9, further comprising the step of forming said nanostructures into nanocone arrays.

13. The method of claim 12, further comprising the step of arranging bases of each of said nanocone arrays to be in close proximity to each other so as to almost be touching but not connected and forming gaps between tips of each of said nanocone arrays.

14. The method of claim 12, further comprising the step of forming said nanocone arrays in a generally pyramidal or cone shape arrays.

15. The method of claim 14, further comprising the step of forming a generally isosceles triangle with an apex angle of approximately 17 degrees.

16. The method of claim 14, further comprising the step of growing substantially roughened surface on each of said nanocone arrays.

17. A device comprising:
a multiple layered semiconductor die, said semiconductor die comprise of;
a sapphire layer at a base of said semiconductor die;
an undoped GaN layer being configured to fuse on top of said sapphire layer;
an n-GaN layer being configured to fuse on top of said Gan layer;
an MQW layer being configured to fuse on top of said n-GaN layer;
a p-GaN layer being configured to fuse on top of said MQW layer.
an ITO layer being configured to fuse on top of said p-GaN layer;
a ZnO seed layer, said seed layer being configured to have a predetermined uniform thickness, said seed layer comprise of generally beveled edges, said seed layer being configured to bond with said ITO layer, said seed layer being configured to form a generally roof shingle pattern with said ITO layer to enhance light emitted by a light source;
a ZnO nanostructure layer, said nanostructure layer being configured to fuse on top of said seed layer, said nanostructure layer comprise of at least two or more nanocone arrays with generally pyramidal or cone shape arrays being configured with bases and tips, said bases of said nanocone arrays being configured to be in close proximity to each other but not connected, wherein said tips of said nanocone arrays being configured to form gaps between each nanocone array; and
a p and n electrodes being configured to fuse with said n-GaN layer.

18. The device of claim 17, in which said nanocone arrays further comprise of generally isosceles triangles with an apex angle of approximately 17 degrees.

19. The device of claim 17, in which said nanocone arrays further comprise of substantially roughened surfaces.

20. The device of claim 17, in which said nanocone arrays comprise of ZnO nanocone arrays.
